(19) United States
(12) Patent Application Publication
(10) Pub. No.: US 2024/0248401 A1
(43) Pub. Date: Jul. 25, 2024

(54) RESIN AND 193 NM DRY PHOTORESIST CONTAINING SAME, AND PREPARATION METHOD THEREFOR AND USE THEREOF

(71) Applicants: SHANGHAI SINYANG SEMICONDUCTOR MATERIALS CO., LTD., Shanghai (CN); CHINA ADVANCED LITHOGRAPHIC MATERIAL TECHNOLOGY CO., LTD., Shanghai (CN)

(72) Inventors: Shunong FANG, Shanghai (CN); Su WANG, Shanghai (CN); Zhiyue GENG, Shanghai (CN)

(21) Appl. No.: 18/616,286

(22) Filed: Mar. 26, 2024

Related U.S. Application Data
(63) Continuation-in-part of application No. PCT/CN2021/124901, filed on Oct. 20, 2021.

(30) Foreign Application Priority Data
Sep. 28, 2021 (CN) 202111158055.1

(51) Int. Cl. G03F 7/039; C08F 220/18; C08F 220/38; C08F 224/00; C08F 232/08; G03F 7/004; G03F 7/038

(52) U.S. Cl. CPC G03F 7/039; C08F 220/18; C08F 220/38; C08F 224/00; C08F 232/08; G03F 7/0045; G03F 7/038

(57) ABSTRACT

Provided are a resin and a 193 nm dry photoresist containing same, and a preparation method therefor and the use thereof. The resin is a copolymer obtained by polymerizing a monomer represented by formula (A), a monomer represented by formula (B), a monomer represented by formula (C), and a monomer represented by formula (D), wherein the resin comprises 42.5-49.5 parts by weight of the monomer represented by formula (A), 1-7.5 parts by weight of the monomer represented by formula (B), 0.25-2.5 parts by weight of the monomer represented by formula (C), and 0.25-2.5 parts by weight of the monomer represented by formula (D). The photoresist containing the resin at least has the following advantages: excellent photosensitivity, a good depth of focus, and a good line width uniformity.

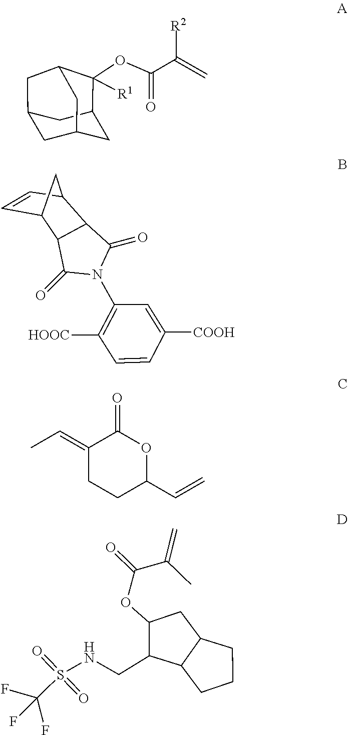

### CROSS-REFERENCE TO RELATED APPLICATIONS

The application is a Continuation-in-part Application of International Application No. PCT/CN2021/124901, filed on Oct. 20, 2021, which claims the priority of Chinese patent application No. 2021111580551 filed on Sep. 28, 2021. The contents of which are incorporated herein by reference in their entireties.

### TECHNICAL FIELD

The present disclosure relates to a resin and 193 nm dry photoresist containing same, and preparation method therefor and use thereof.

### BACKGROUND

Lithography refers to a pattern micromachining technique that transfers a pattern designed on a mask onto a substrate by means of exposure, development, etching and other processes using the chemical sensitivity of a lithographic material (specifically a photoresist) under the action of visible light, ultraviolet light, electron beams, etc. A lithographic material (specifically a photoresist), also known as a photoresist, is the most critical functional chemical material involved in lithography, the main components thereof being a resin, a photo acid generator (PAG), and corresponding additives and solvents. A photoacid generator is a photosensitive compound, which is decomposed under the illumination to produce an acid, and the acid thus produced can allow a decomposition or cross-linking reaction of an acid-sensitive resin, thereby increasing the dissolution contrast between an illuminated portion and a non-illuminated portion in a developing solution and being applicable to the technical field of pattern micromachining.

The three important parameters of a photoresist, including resolution, sensitivity and line width roughness, determine the process window of the photoresist during chip manufacturing. With the continuous improvement of the performance of semiconductor chips, the integration level of integrated circuits increases exponentially, and patterns in integrated circuits become smaller and smaller. In order to fabricate smaller patterns, it is necessary to improve the above-mentioned three performance indexes of a photoresist. According to the Rayleigh equation, the resolution of a photoresist can be improved by using a short-wavelength light source in a photolithography process. The wavelength of a light source used in a photolithography process has developed from 365 nm (I-line) to 248 nm (KrF), 193 nm (ArF) and 13 nm (EUV). In order to improve the sensitivity of a photoresist, a chemically amplified photosensitive resin is currently used in mainstream KrF, ArF and EUV photoresists. Therefore, a photoacid generator matched with a chemically amplified photosensitive resin is widely used in high-end photoresists.

With the gradual development of a photolithography process to a 193-nm dry exposure process, the complexity of the process increases, and there are increasingly higher requirements on a resist (i.e. photoresist). It has become an urgent problem to be solved in the industry to develop a resist that can improve the resolution, sensitivity and line width roughness of a photoresist.

### BRIEF SUMMARY OF THE INVENTION

Given the above problems in the prior art, the disclosure aims to provide a resin and 193 nm dry photoresist containing same, preparation method therefor and use thereof. The photoresist containing a resin of the present disclosure has at least the following advantages: excellent photosensitivity, good depth of focus (DOF), and good critical dimension uniformity (CDU).

The present disclosure provides a resin, which is a copolymer obtained by polymerizing a monomer of formula (A), a monomer of formula (B), a monomer of formula (C), and a monomer of formula (D);
wherein, in parts by weight, the monomer of formula (A) is 42.5 to 49.5 parts by weight, the monomer of formula (B) is 1 to 7.5 parts by weight, the monomer of formula (C) is 0.25 to 2.5 parts by weight, and the monomer of formula (D) is 0.25 to 2.5 parts by weight;
the molecular weight distribution coefficient of the resin is 1.5 to 2.0;

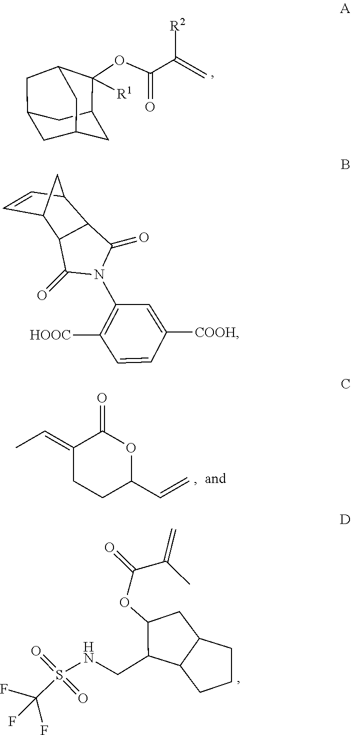

wherein R¹ is C₁-C₁₀ alkyl, and R² is H or methyl.

In one embodiment of the present disclosure, R¹ can be C₁-C₄ alkyl, such as methyl.

In one embodiment of the present disclosure, R² can be methyl.

In one embodiment of the present disclosure, the monomer of formula (A) can be

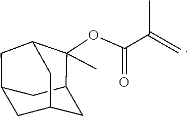 [SMILES: C=C(C)C(=O)OC1(C)C2CC3CC(C2)CC1C3]

In one embodiment of the present disclosure, in parts by weight, the monomer of formula (A) can be 42.5 to 46 parts by weight.

In one embodiment of the present disclosure, in parts by weight, the monomer of formula (B) can be 2.5 to 4 parts by weight.

In one embodiment of the present disclosure, in parts by weight, the monomer of formula (C) can be 0.5 to 1.25 parts by weight.

In one embodiment of the present disclosure, in parts by weight, the monomer of formula (D) can be 0.5 to 1.25 parts by weight.

In one embodiment of the present disclosure, the weight average molecular weight (Mw) of the resin can be 5000 to 10000.

In one embodiment of the present disclosure, the molecular weight distribution coefficient of the resin can be 1.5, 1.7 or 2.0. The molecular weight distribution coefficient refers to the ratio of the weight average molecular weight to the number average molecular weight (Mw/Mn) of the resin.

In one embodiment of the present disclosure, the resin can be selected from any one of the following resins:
resin 1: in parts by weight, the monomer of formula (A) is 45 parts by weight, the monomer of formula (B) is 4 parts by weight, the monomer of formula (C) is 0.25 parts by weight, and the monomer of formula (D) is 0.75 parts by weight;
resin 2: in parts by weight, the monomer of formula (A) is 42.5 parts by weight, the monomer of formula (B) is 4 parts by weight, the monomer of formula (C) is 1.75 parts by weight, and the monomer of formula (D) is 1.75 parts by weight;
resin 3: in parts by weight, the monomer of formula (A) is 49.5 parts by weight, the monomer of formula (B) is 1 parts by weight, the monomer of formula (C) is 0.75 parts by weight, and the monomer of formula (D) is 0.75 parts by weight;
resin 4: in parts by weight, the monomer of formula (A) is 42.5 parts by weight, the monomer of formula (B) is 7.5 parts by weight, the monomer of formula (C) is 1.5 parts by weight, and the monomer of formula (D) is 1 parts by weight.

In the resin 1, the weight average molecular weight of the resin can be 9800; the molecular weight distribution coefficient of the resin can be 2.

In the resin 2, the weight average molecular weight of the resin can be 6400. The molecular weight distribution coefficient of the resin can be 1.7.

In the resin 3, the weight average molecular weight of the resin can be 6300. The molecular weight distribution coefficient of the resin can be 1.5.

In the resin 4, the weight average molecular weight of the resin can be 7200. The molecular weight distribution coefficient of the resin can be 1.7.

In one embodiment of the present disclosure, the resin can be prepared by a preparation method as follows, wherein the preparation method for the resin comprises the following steps: carrying out a polymerization reaction involving the monomer of formula (A), the monomer of formula (B), the monomer of formula (C), and the monomer of formula (D) in an organic solvent to obtain the resin.

In one embodiment of the present disclosure, in the preparation method for the resin, in parts by weight, the organic solvent is 50 to 300 parts by weight, such as 100 parts by weight.

In one embodiment of the present disclosure, in the preparation method for the resin, the organic solvent can be one or more of propylene glycol methyl ether acetate, propylene glycol diacetate, methylenebisacrylamide, N-methylpyrrolidone, ethyl 3-ethoxypropionate and cyclohexanone and dichloromethane, such as propylene glycol methyl ether acetate (PGMEA).

In one embodiment of the present disclosure, in the preparation method for the resin, the polymerization reaction can be carried out under an inert gas (such as nitrogen).

In one embodiment of the present disclosure, in the preparation method for the resin, the polymerization reaction can be initiated by a free radical initiator or by heating.

When the polymerization reaction is initiated by a free radical initiator, the free radical initiator is preferably one or more of 2,2′-azobisisobutyronitrile (AIBN), 2,2′-azobis(2,4-dimethylvaleronitrile), 2,2′-azobis(methyl 2-methylpropionate), benzoyl peroxide, and lauroyl peroxide.

When the polymerization reaction is initiated by heating, in the polymerization reaction, the polymerization temperature is preferably 50 to 150° C., more preferably 60 to 90° C., such as 70° C.

In one embodiment of the present disclosure, in the preparation method for the resin, the time of the polymerization reaction can be a conventional one in the art, such as 6 to 12 hours, or such as 8 hours.

In one embodiment of the present disclosure, in the preparation method for the resin, the polymerization reaction further comprises post-treatment steps, such as one or more of cooling, precipitation, and drying.

Herein, the solvent used in the precipitation can be an alcohol solvent, such as methanol.

Herein, the drying can be vacuum drying (e.g. vacuum drying at 40° C. for 24 hours).

In one embodiment of the present disclosure, the preparation method for the resin comprises the following steps: adding a solution of the monomer of formula (A), the monomer of formula (B), the monomer of formula (C), and the monomer of formula (D) and part of the organic solvent, to the rest of the organic solvent.

Preferably, the mass ratio of the part of the organic solvent to the rest of the organic solvent is 1:1 to 5:1, such as 7:3. The adding mode is dropwise addition. The time of addition is 1 to 8 hours, such as 5 hours.

The present disclosure provides a photoresist composition comprising the resin as described above, a photoacid generator, and a solvent.

In one embodiment of the present disclosure, in the photoresist composition, the photoacid generator can be any known photoacid generator conventionally used in photoresists, especially in chemically amplified photoresist compositions. For the purpose of finely tuning the performance of photolithography, the photoacid generator can be any compound capable of generating acid upon exposure to high-energy radiation, such as one or more of sulfonium salt, iodonium salt, sulfonyldiazomethane, N-sulfonyloxyimide, and oxime-O-sulfonate.

Herein, examples of the acid generated by the photoacid generator include strong acid such as sulfonic acid, bis(perfluoroalkanesulfonyl)imide, and tri(perfluoromethylsulfonyl)methide anion (methide), and weak acids such as carboxylic acid.

In one embodiment of the present disclosure, in the photoresist composition, the photoacid generator may have a structure of formula (I):

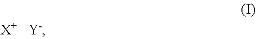

wherein X⁺ is selected from any one of the following structures:

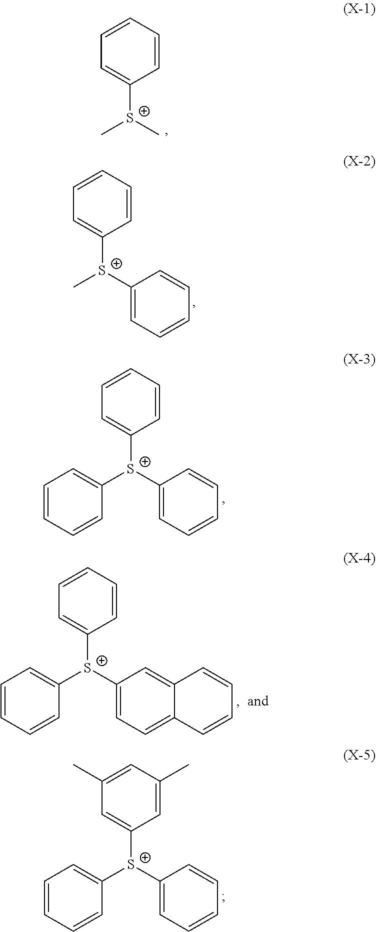

Y⁻ is selected from any one of the following structures:

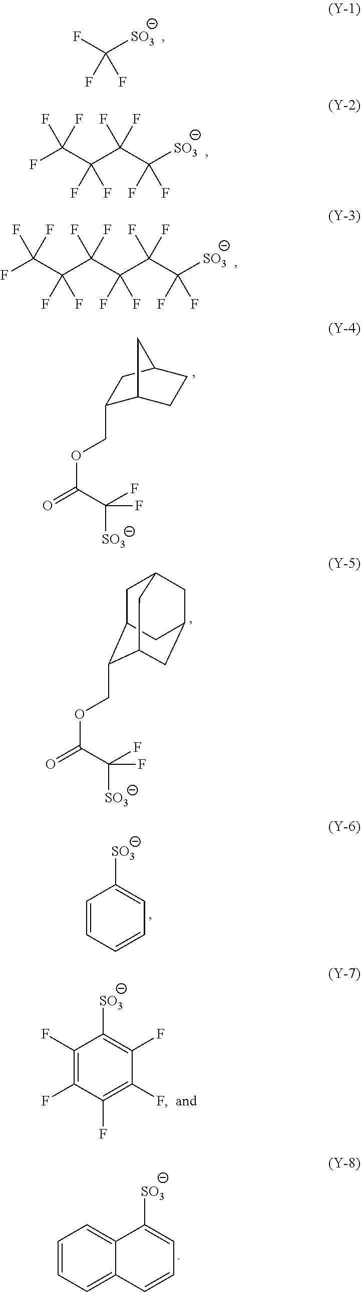

In one embodiment of the present disclosure, in the photoresist composition, the photoacid generator can be selected from any one of the following structures:

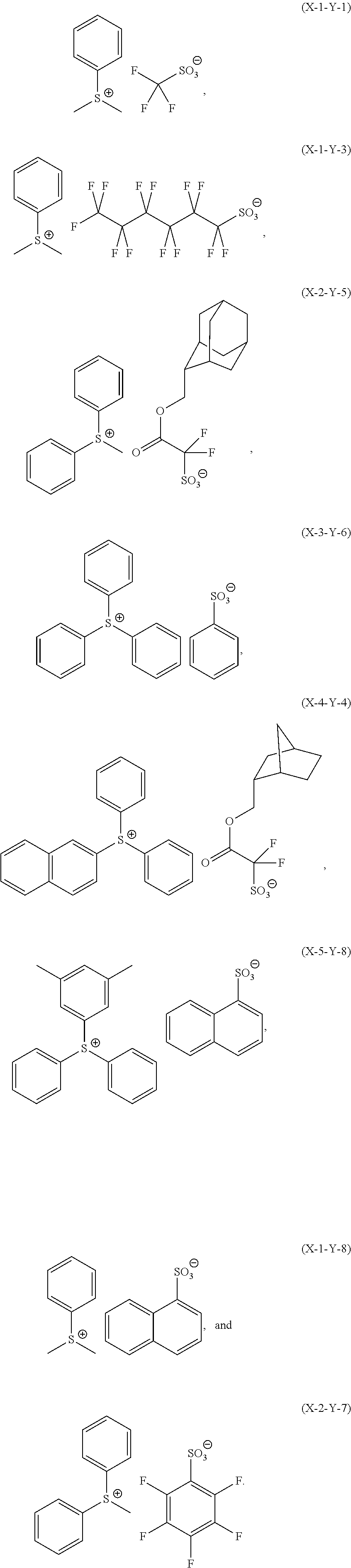

In one embodiment of the present disclosure, in the photoresist composition, the solvent can be any known solvent conventionally used in photoresist, especially in chemically amplified photoresist compositions. The solvent can be one or more of ketone solvent (e.g., cyclohexanone and/or methyl-2-pentanone), alcohol solvent (e.g., monohydric alcohol (e.g., 3-methoxybutanol, 3-methyl-3-methoxybutanol, 1-methoxy-2-propanol, and 1-ethoxy-2-propanol) and/or dihydric alcohol (e.g., diacetone alcohol)), ether solvent (e.g., one or more of propylene glycol monomethyl ether, ethylene glycol monomethyl ether, propylene glycol monoethyl ether, ethylene glycol monoethyl ether, propylene glycol dimethyl ether, and diethylene glycol dimethyl ether), and ester solvent (e.g., one or more of propylene glycol monomethyl ether acetate (PGMEA), propylene glycol monoethyl ether acetate, methyl lactate, ethyl pyruvate, butyl acetate, 3-methoxypropyl acetate, 3-ethoxypropyl acetate, tert-butyl acetate, tert-butyl propionate, propylene glycol monobutyl ether acetate, and γ-butyrolactone).

In one embodiment of the present disclosure, in the photoresist composition, the solvent can be one or more of ketone solvent, ether solvent and ester solvent, such as one or more of cyclohexanone, ethylene glycol monoethyl ether and γ-butyrolactone.

In one embodiment of the present disclosure, the photoresist composition may further comprise an additive, the additive can be any known additive conventionally used in photoresist, especially in chemically amplified photoresist composition, such as a quencher and/or a surfactant.

In one embodiment of the present disclosure, in the photoresist composition, the quencher is a compound capable of inhibiting the diffusion rate of the acid generated by the photoacid generator when it diffuses through the resist film, for example, the quencher can be one or more of amine compound, sulfonate and carboxylate. The amine compound can be primary, secondary, and tertiary amine compounds, such as amine compounds having hydroxyl, ether, ester, lactone, cyano, or sulfonate ester groups. Particularly when the resist composition comprises a base-unstable component, the protected amine compounds are effective.

In one embodiment of the present disclosure, in the photoresist composition, the quencher can be

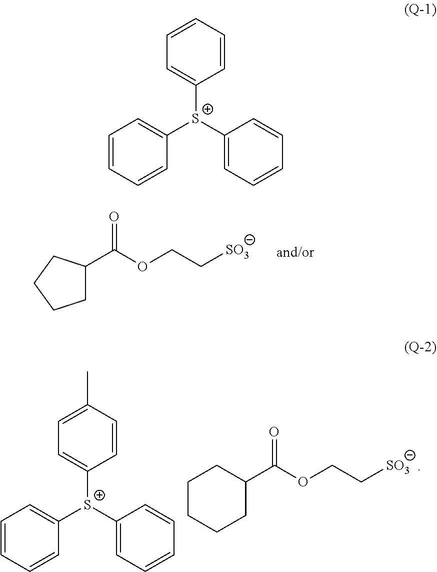

In one embodiment of the present disclosure, in the photoresist composition, the surfactant can be a surfactant that is insoluble or substantially insoluble in water but soluble in an alkaline developer, and/or a surfactant that is insoluble or substantially insoluble in both water and an alkaline developer.

In one embodiment of the present disclosure, in the photoresist composition, the surfactant can be one or more of FC-4430 (purchased from 3M), S-381 (purchased from AGC Seimi Chemical), E1004 (purchased from Air Products), KH-20, and KH-30 (purchased from Asahi Glass), such as KH-20 and/or KH-30.

In the photoresist composition, the content of each component is the conventional content in the photoresist in the art, and is preferably as follows in the present disclosure.

In one embodiment of the present disclosure, in the photoresist composition, in parts by weight, the resin can be 75 to 95 parts by weight (such as 85 parts by weight).

In one embodiment of the present disclosure, in the photoresist composition, in parts by weight, the photoacid generator can be 1 to 10 parts by weight (such as 7 parts by weight).

In one embodiment of the present disclosure, in the photoresist composition, in parts by weight, the solvent can be 1000 to 2000 parts by weight (such as 1500 parts by weight).

In one embodiment of the present disclosure, in the photoresist composition, in parts by weight, the quencher can be 0.5 to 3 parts by weight (such as 2 parts by weight).

In one embodiment of the present disclosure, in the photoresist composition, in parts by weight, the surfactant can be 0.1 to 0.2 parts by weight (such as 0.15 parts by weight).

In one embodiment of the present disclosure, the photoresist composition may comprise the following components: the resin as described above, the photoacid generator as described above, the solvent as described above, the quencher as described above and the surfactant as described above.

In one embodiment of the present disclosure, the photoresist composition can be selected from any one of the following combinations 1-4:
combination 1: in parts by weight, resin 1 is 85 parts by weight, the photoacid generator X-1-Y-1 is 7 parts by weight, the solvent cyclohexanone is 1500 parts by weight, the quencher Q-1 is 2 parts by weight, the surfactant KH-30 is 0.15 parts by weight;
combination 2: in parts by weight, resin 2 is 85 parts by weight, the photoacid generator X-1-Y-1 is 7 parts by weight, the solvent cyclohexanone is 1500 parts by weight, the quencher Q-1 is 2 parts by weight, the surfactant KH-30 is 0.15 parts by weight;
combination 3: in parts by weight, resin 3 is 85 parts by weight, the photoacid generator X-1-Y-1 is 7 parts by weight, the solvent cyclohexanone is 1500 parts by weight, the quencher Q-1 is 2 parts by weight, the surfactant KH-30 is 0.15 parts by weight;
combination 4: in parts by weight, resin 4 is 85 parts by weight, the photoacid generator X-1-Y-1 is 7 parts by weight, the solvent cyclohexanone is 1500 parts by weight, the quencher Q-1 is 2 parts by weight, the surfactant KH-30 is 0.15 parts by weight;
wherein, in the resin 1: in parts by weight, the monomer of formula (A) is 45 parts by weight, the monomer of formula (B) is 4 parts by weight, the monomer of formula (C) is 0.25 parts by weight, and the monomer of formula (D) is 0.75 parts by weight;
in the resin 2: in parts by weight, the monomer of formula (A) is 42.5 parts by weight, the monomer of formula (B) is 4 parts by weight, the monomer of formula (C) is 1.75 parts by weight, and the monomer of formula (D) is 1.75 parts by weight;
in the resin 3: in parts by weight, the monomer of formula (A) is 49.5 parts by weight, the monomer of formula (B) is 1 parts by weight, the monomer of formula (C) is 0.75 parts by weight, and the monomer of formula (D) is 0.75 parts by weight;
in the resin 4: in parts by weight, the monomer of formula (A) is 42.5 parts by weight, the monomer of formula (B) is 7.5 parts by weight, the monomer of formula (C) is 1.5 parts by weight, and the monomer of formula (D) is 1 parts by weight.

The present disclosure provides a preparation method for the photoresist composition as described above, the preparation method comprising the following steps: mixing the components of the photoresist composition as described above uniformly.

In the preparation method for the photoresist composition, after the mixing, it may further comprise a filtration step. The method of the filtration can be conventional in the art, preferably to use a filter for filtering. The pore size of the filter membrane of the filter is preferably 0.2 μm.

The present disclosure provides a method for forming a photolithographic pattern, comprising the following steps:
S1: coating the substrate surface with the photoresist composition as described above, and baking to form a photoresist layer;
S2: exposing the photoresist layer formed in S1;
S3: baking the exposed photoresist layer exposed in S2;
S4: developing the baked photoresist layer baked in S3.

In S1, the substrate can be a substrate for the manufacture of integrated circuits (such as one or more of S1, SiO₂, SiN, SiON, TiN, WSi, BPSG, SOG, and organic anti-reflective film), or a substrate for the manufacture of mask circuits (such as one or more of Cr, CrO, CrON, MoSi₂, and SiO₂).

In S1, the method of coating can be a conventional one used in the art for forming a photolithographic pattern, such as spin coating.

In S1, the baking temperature can be a conventional one used in the art for forming a photolithographic pattern, such as 120-250° C., or such as 130° C.

In S1, the baking time can be a conventional one used in the art for forming a photolithographic pattern, such as 1 to 10 minutes, or such as 1 minute.

In S1, the thickness of the photoresist layer can be 0.05 to 2 μm, such as 300 nm.

In S2, the exposure can be carried out using conventional operations used in the art for forming photolithographic patterns, such as high-energy radiation (e.g., KrF excimer laser, ArF excimer laser, or EUV), wherein the dose of exposure can be 1 to 200 mJ/cm² (such as 10 to 100 mJ/cm²), or using electron beam exposure, wherein the dose of exposure can be 0.1 to 100 μC/cm² (such as 0.5 to 50 μC/cm²).

In S2, the exposure can be performed by a conventional photolithography method or a dry photolithography method.

In S2, in the case of dry photolithography, a water-insoluble protective film can be formed on the resist film. Water-insoluble protective films for dry photolithography are generally of two types when used to prevent any component from leaching out of the photoresist layer and to improve water slippage at the film surface. The first type is an organic solvent strippable protective film, which must be stripped with an organic solvent in which the resist film is insoluble before alkaline development. The second type is an alkali-soluble protective film that is soluble in an alkaline developer so that it can be removed at the same time as the area of dissolution of the resist film is removed. The second type of the protective film preferably comprises a polymer with 1,1,1,3,3,3-hexafluoro-2-propanol residues (which are insoluble in water but soluble in an alkaline developer) as abase material. These polymers are soluble in alcohols with at least 4 carbon atoms, ethers with 8 to 12 carbon atoms, or a mixture thereof. Alternatively, the aforementioned surfactant, which is insoluble in water and soluble in an alkaline developer, can be dissolved in an alcohol solvent with at least 4 carbon atoms, an ether solvent with 8 to 12 carbon atoms, or a mixture thereof to form the material for the second type of protective film.

In S3, the baking temperature can be a conventional baking temperature used in the art for forming photolithographic patterns, such as 60 to 150° C., or such as 80 to 140° C., or such as 115° C.

In S3, the baking time can be a conventional baking time used in the art for forming photolithographic patterns, such as 1 to 3 minutes, or such as 1 minute.

In S3, after the baking, the step can further comprise a step of cooling, such as cooling to 10-30° C., preferably to 23° C.

In S4, the method of development can be a conventional method of development used in the art for forming photolithographic patterns, such as one or more of immersion, spin-coating immersion, and spraying.

In S4, the developer used for the development can be a conventional developer used in the art for forming photolithographic patterns, such as an alkaline aqueous solution and/or an organic solvent.

The alkaline aqueous solution can be an alkaline aqueous solution of a developer, such as 0.1-5 wt %, preferably 2-3 wt % of tetramethylammonium hydroxide (TMAH) aqueous solution.

The organic solvent can be one or more of 2-octanone, 2-nonanone, 2-heptanone, 3-heptanone, 4-heptanone, 2-hexanone, 3-hexanone, diisobutyl ketone, methyl cyclohexanone, acetophenone, methyl acetophenone, propyl acetate, butyl acetate, isobutyl acetate, pentyl acetate, isopentyl acetate, butenyl acetate, benzyl acetate, propyl formate, butyl formate, isobutyl formate, pentyl formate, isopentyl formate, methyl valerate, methyl crotonate, methyl ricinoleate, ethyl ricinoleate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, benzyl acetate, methyl phenylacetate, benzyl formate, ethyl phenylformate, methyl 3-phenylpropionate, benzyl propionate, ethyl phenylacetate, and ethyl 2-phenylacetate.

In S4, the development temperature can be a conventional development temperature used in the art for forming photolithographic patterns, such as 10-30° C., preferably 23° C.

In S4, the development time can be a conventional development time used in the art for forming photolithographic patterns, such as 0.1-3 minutes, such as 0.5-2 minutes, or such as 1 minute.

On the basis of conforming to common knowledge in the art, the above-mentioned preferred conditions can be arbitrarily combined to obtain various preferred embodiments of the present disclosure.

In the present disclosure, dry lithography is a 193 nm exposure lithography method distinguished from 193 nm (ArF) immersion exposure lithography, and is commonly known in the art as dry-type lithography.

Reagents and raw materials used in the present disclosure are all commercially available.

The positive effects of the present disclosure lie in: the photoresist comprising the resin of the present disclosure has at least the following advantages: excellent photosensitivity, a good depth of focus (DOF), and a good critical dimension uniformity (CDU).

### DETAILED DESCRIPTION OF THE INVENTION

The present disclosure is further described below by way of examples; however, the present disclosure is not limited to the scope of the described examples. For the experimental methods in which no specific conditions are specified in the following examples, selections are made according to conventional methods and conditions or according to the product instructions.

### Preparation of Resin:

Under a nitrogen atmosphere, a solution was prepared by dissolving the following monomer A, monomer B, monomer C, monomer D in 70 g of propylene glycol monomethyl ether acetate (PGMEA) according to the parts by weight (g) in Table 1. Under a nitrogen atmosphere, this solution was then dropwise added to 30 g of propylene glycol monomethyl ether acetate (PGMEA) over 5 hours, with stirring at 70° C. After the dropwise addition is complete, stirring was continued at 70° C. for 3 hours. The reaction solution was cooled to room temperature and added dropwise to 1000 g of methanol. The precipitated solid was collected by filtration and dried in vacuum at 40° C. for 24 hours to obtain a polymer in the form of powder solid.

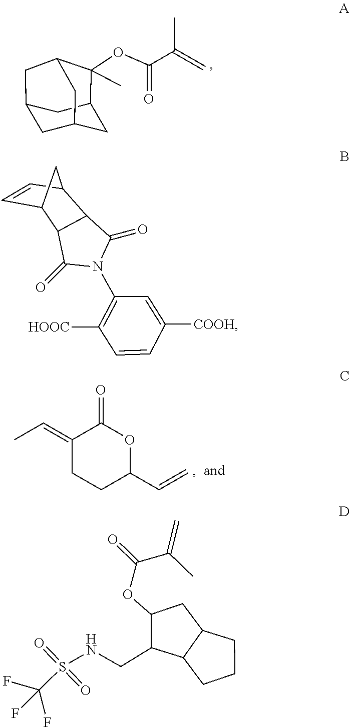

TABLE 1

| | Mono- | Mono- | Mono- | Mono- | | |
|---|---|---|---|---|---|---|
| Resin | mer A | mer B | mer C | mer D | | Mw/ |
| No. | (g) | (g) | (g) | (g) | Mw | Mn |
| R-1 | 45 | 4 | 0.25 | 0.75 | 9800 | 2 |
| R-2 | 42.5 | 4 | 1.75 | 1.75 | 6400 | 1.7 |
| R-3 | 49.5 | 1 | 0.75 | 0.75 | 6300 | 1.5 |
| R-4 | 42.5 | 7.5 | 1.5 | 1 | 7200 | 1.7 |
| CR-1 | 47.5 | 0 | 1.25 | 1.25 | 6000 | 1.8 |
| CR-2 | 39 | 7.5 | 2 | 1.5 | 9900 | 1.5 |
| CR-3 | 39 | 7.5 | 2.5 | 1 | 7400 | 2 |
| CR-4 | 50.25 | 0.25 | 0.25 | 0.25 | 7500 | 2 |

### Examples 1 to 4 and Comparative Examples 1 to 13: Preparation of Photoresist

According to the formulations in Table 2, the resin prepared by the above preparation, photoacid generator, and quencher were dissolved in an organic solvent, and the photoresists of Examples 1 to 4 and Comparative Examples 1 to 13 in solution form were prepared by filtration through a filter with a pore size of 0.2 μm, wherein

The polymers used in Table 2 are the resins prepared according to Table 1.

The photoacid generators used in Table 2 have the following structures:

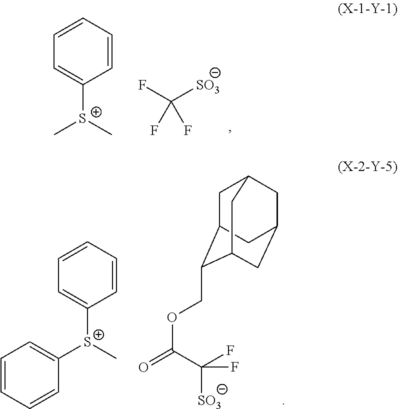

The quenchers used in Table 2 have the following structures:

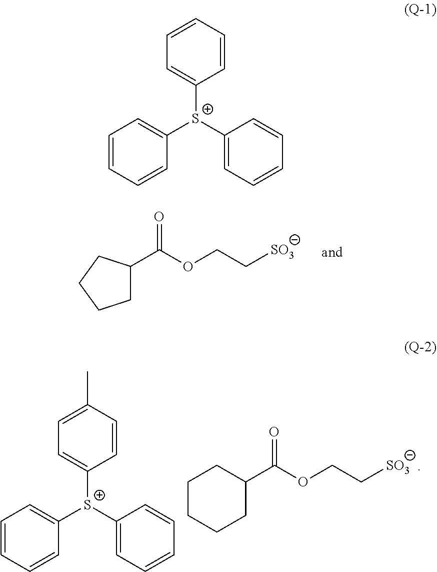

The organic solvents used in Table 2 were cyclohexanone (S-1), ethylene glycol monoethyl ether (S-2), and γ-butyrolactone (S-3), and the organic solvents comprise 0.01 wt % of the surfactant KH-30 or KH-20 (Asahi Glass Co., Ltd.).

TABLE 2

| | | | | Photoacid | | | | | | |
|---|---|---|---|---|---|---|---|---|---|---|
| | | Resin | | generator | | Solvent | | Quencher | | |
| | Photo | | Parts | | Parts | | Parts | | Parts | Sur- |
| Example | resist | | by | | by | | by | | by | factant |
| No. | No. | Types | weight | Types | weight | Types | weight | Types | Weight | Types |
| Example 1 | P-1 | R-1 | 85 | X-1-Y-1 | 7 | S-1 | 1500 | Q-1 | 2 | KH-30 |
| Example 2 | P-2 | R-2 | 85 | X-1-Y-1 | 7 | S-1 | 1500 | Q-1 | 2 | KH-30 |
| Example 3 | P-3 | R-3 | 85 | X-1-Y-1 | 7 | S-1 | 1500 | Q-1 | 2 | KH-30 |
| Example 4 | P-4 | R-4 | 85 | X-1-Y-1 | 7 | S-1 | 1500 | Q-1 | 2 | KH-30 |
| Comparative | CP-1 | CR-1 | 80 | X-1-Y-1 | 3 | S-1 | 1200 | Q-1 | 0.8 | KH-30 |
| example 1 | | | | | | | | | | |
| Comparative | CP-2 | CR-2 | 90 | X-1-Y-1 | 5 | S-1 | 1600 | Q- | 1.5 | KH-30 |
| example 2 | | | | | | | | | | |
| Comparative | CP-3 | CR-3 | 95 | X-1-Y-1 | 10 | S-1 | 2000 | Q-1 | 3 | KH-30 |
| example 3 | | | | | | | | | | |
| Comparative | CP-4 | CR-4 | 85 | X-2-Y-5 | 7 | S-1 | 1500 | Q-1 | 2 | KH-30 |
| example 4 | | | | | | | | | | |
| Comparative | CP-5 | CR-1 | 85 | X-1-Y-1 | 7 | S2 | 1500 | Q-1 | 2 | KH-30 |
| example 5 | | | | | | | | | | |
| Comparative | CP-6 | CR-1 | 85 | X-1-Y-1 | 7 | S3 | 1500 | Q-1 | 2 | KH-30 |
| example 6 | | | | | | | | | | |
| Comparative | CP-7 | CR-1 | 85 | X-1-Y-1 | 7 | S-1 | 1500 | Q-2 | 2 | KH-30 |
| example 7 | | | | | | | | | | |
| Comparative | CP-8 | CR-2 | 85 | X-1-Y-1 | 7 | S-1 | 1500 | Q-1 | 2 | KH-20 |
| example 8 | | | | | | | | | | |
| Comparative | CP-9 | CR-2 | 85 | X-1-Y-1 | 7 | S-1 | 1500 | Q-1 | 2 | KH-30 |
| example 9 | | | | | | | | | | |
| Comparative | CP-10 | CR-2 | 85 | X-1-Y-1 | 7 | S-1 | 1500 | Q-1 | 2 | KH-30 |
| example 10 | | | | | | | | | | |
| Comparative | CP-11 | CR-3 | 85 | X-1-Y-1 | 7 | S-1 | 1500 | Q-1 | 2 | KH-30 |
| example 11 | | | | | | | | | | |
| Comparative | CP-12 | CR-3 | 85 | X-1-Y-1 | 7 | S-1 | 1500 | Q-1 | 2 | KH-30 |
| example 12 | | | | | | | | | | |
| Comparative | CP-13 | CR-4 | 85 | X-1-Y-1 | 7 | S-1 | 1500 | Q-1 | 2 | KH-30 |
| example 13 | | | | | | | | | | |

### Application and Effect Examples

### ArF Dry Lithography Pattern Test (Hole Pattern Test)

### 1. Hole Pattern Formation:

A photoresist was spin-coated onto a silicon wafer covered with an anti-reflective coating (ARC29A, Nissan Chemical Co., Ltd., thickness 78 nm) and heat-treated at 130° C. for 60 seconds to form a 300 nm thick photoresist film. Exposure is performed in an ArF excimer laser stepper (Nikon Corp., NA=0.68) with an exposure dose of 45 mJ/cm², followed by a heat-treatment at 115° C. for 60 seconds, cooled to 23° C., and developed in a 2.38% tetramethylammonium hydroxide aqueous solution by spin-coating immersion for 60 seconds, thereby forming a hole pattern with 100 nm spacing.

### 2. Photosensitivity Evaluation:

The hole pattern formed as described above was observed under a TD-SEM (CG-4000, Hitachi High-Technologies Corp.). The optimal dose (Eop) is the exposure dose (mJ/cm²) that provides a hole diameter of 50 nm at 100 nm spacing and is used as an index for photosensitivity.

### 3. Depth of Focus (DOF) Margin Evaluation:

The hole size at the optimal dose was measured under TD-SEM (CG-4000), and the DOF margin providing a size of 50 nm±5 nm was determined. A larger value indicates smaller changes in pattern size with changes in DOF, and therefore, a better DOF margin.

### 4. CDU Evaluation:

The hole pattern formed as described is observed under TD-SEM (CG-4000), and the diameters of 125 holes are measured. The triple value (36) of the standard deviation (a) is calculated and recorded as CDU. A smaller value of 36 indicates a smaller deviation of the hole.

### 5. PPD Evaluation:

Immediately after PEB (with no delay, PPD=0 h), the wafer is developed by suspension immersion for 30 seconds to form a hole pattern with a diameter of 50 nm and a spacing of 100 nm. In another operation, the wafer was kept for 6 hours (PPD=6 hours) after PEB, and then it was similarly developed to form a pattern.

The hole patterns at PPD=0 h and 6 h were observed under TD-SEM (CG-4000), and the diameters of 125 holes were measured. The average is taken as the hole size (CD), and CDU was calculated using the same method as above. The difference between the CD at PPD 0 h and the CD at PPD 6 h was taken as the CD shrinkage caused by PPD(ΔPPD CD).

The effects of the photoresists prepared in examples 1 to 4 and the photoresists prepared in comparative examples 1 to 13 are shown in Table 3.

The developers used in Table 3 are butyl acetate (D-1), 2-heptanone (D-2), and methyl benzoate (D-3).

TABLE 3

| | | | | | | | CDU | | CDU | |
|---|---|---|---|---|---|---|---|---|---|---|
| | | | | | | CD | (3σ, | CD | (3σ, | |
| | | | | | | (nm) | nm) | (nm) | nm) | |
| Photo- | PEB | | Eop | | | At | At | At | At | ΔPPD |
| resist | temperature | | (mJ/ | DOF | CDU | PPD | PPD | PPD | PPD | CD |
| No. | (° C.) | Developers | cm²) | (nm) | (nm) | 0 h | 0 h | 6 h | 6 h | (nm) |
| P-1 | 100 | D-1 | 37.4 | 110 | 4 | 48.7 | 6.5 | 45.2 | 6.7 | 3.5 |
| P-2 | 95 | D-1 | 32.1 | 90 | 4 | 46.1 | 5.4 | 42.9 | 5.7 | 3.2 |
| P-3 | 100 | D-1 | 36.8 | 100 | 3.9 | 49.1 | 6 | 45.3 | 6.2 | 3.8 |
| P-4 | 90 | D-1 | 38.9 | 120 | 3.9 | 42.7 | 5.8 | 38.9 | 6.1 | 3.8 |
| CP-1 | 100 | D-1 | 35.4 | 50 | 5.4 | 46.9 | 5.3 | 41.4 | 5.5 | 5.5 |
| CP-2 | 90 | D-1 | 34.3 | 80 | 4.6 | 48.6 | 5.6 | 44.5 | 5.7 | 4.1 |
| CP-3 | 95 | D-1 | 33.4 | 80 | 6 | 48 | 5.5 | 41.3 | 5.8 | 6.7 |
| CP-4 | 90 | D-1 | 28.2 | 60 | 4.7 | 46.2 | 5.4 | 39.3 | 5.7 | 6.9 |
| CP-5 | 90 | D-1 | 29.2 | 80 | 4.4 | 41.1 | 6.3 | 34.5 | 6.4 | 6.6 |
| CP-6 | 95 | D-1 | 27.6 | 80 | 4.5 | 46.1 | 5 | 40.3 | 5.2 | 5.8 |
| CP-7 | 100 | D-1 | 28.2 | 80 | 4 | 49.8 | 5.5 | 44.2 | 5.8 | 5.6 |
| CP-8 | 90 | D-1 | 38.9 | 70 | 6 | 40.2 | 5.5 | 33.4 | 5.8 | 6.8 |
| CP-9 | 95 | D-2 | 39 | 60 | 5.4 | 43.2 | 6.1 | 36.5 | 6.4 | 6.7 |
| CP-10 | 100 | D-1 | 32.4 | 60 | 5.1 | 41 | 6.2 | 37 | 6.4 | 4 |
| CP-11 | 90 | D-1 | 30.9 | 70 | 5.4 | 49.6 | 5.7 | 45.6 | 5.8 | 4 |
| CP-12 | 95 | D-1 | 28.4 | 60 | 6 | 45.9 | 5.4 | 39.3 | 5.7 | 6.6 |
| CP-13 | 90 | D-1 | 29.8 | 70 | 5.5 | 53.5 | 5.8 | 46.6 | 6.1 | 6.9 |

As can be seen from Table 3 above, the photoresist compositions within the scope of the present disclosure, compared with the comparative photoresist compositions, show improvements in DOF and CDU, and a reduction in CD shrinkage caused by PPD (i.e., smaller CD changes).

What is claimed is:

1. A resin, wherein the resin is a copolymer obtained by polymerizing a monomer of formula (A), a monomer of formula (B), a monomer of formula (C), and a monomer of formula (D);
wherein, in parts by weight, the monomer of formula (A) is 42.5 to 49.5 parts by weight, the monomer of formula (B) is 1 to 7.5 parts by weight, the monomer of formula (C) is 0.25 to 2.5 parts by weight, and the monomer of formula (D) is 0.25 to 2.5 parts by weight;
the molecular weight distribution coefficient of the resin is 1.5 to 2.0; 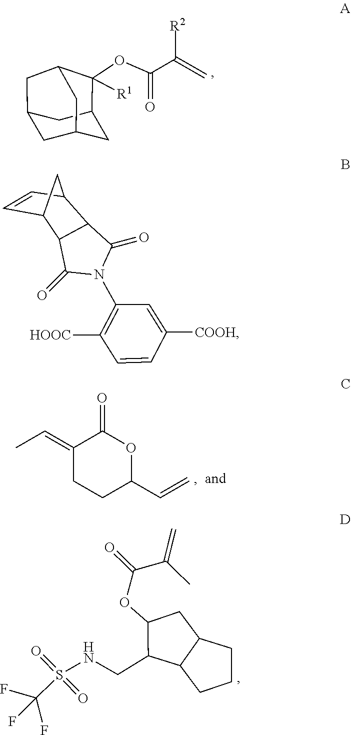
wherein R¹ is C₁-C₁₀ alkyl and R² is H or methyl.

2. The resin according to claim 1, wherein R¹ is C₁-C₄ alkyl;
or R² is methyl.

3. The resin according to claim 1, wherein R¹ is methyl.

4. The resin according to claim 1, wherein the monomer of formula (A) is 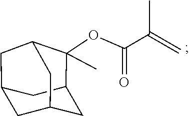 [SMILES: C=C(C)C(=O)OC1(C)C2CC3CC(C2)CC1C3]
or in parts by weight, the monomer of formula (A) is 42.5 to 46 parts by weight;
or in parts by weight, the monomer of formula (B) is 2.5 to 4 parts by weight;
or in parts by weight, the monomer of formula (C) is 0.5 to 1.25 parts by weight;
or in parts by weight, the monomer of formula (D) is of 0.5 to 1.25 parts by weight;
or the weight average molecular weight of the resin is 5000 to 10000;
or the molecular weight distribution coefficient of the resin is 1.5, 1.7 or 2.0.

5. The resin according to claim 1, wherein the resin is selected from any one of the following resins;
resin 1: in parts by weight, the monomer of formula (A) is 45 parts by weight, the monomer of formula (B) is 4 parts by weight, the monomer of formula (C) is 0.25 parts by weight, and the monomer of formula (D) is 0.75 parts by weight;
resin 2: in parts by weight, the monomer of formula (A) is 42.5 parts by weight, the monomer of formula (B) is 4 parts by weight, the monomer of formula (C) is 1.75 parts by weight, and the monomer of formula (D) is 1.75 parts by weight;
resin 3: in parts by weight, the monomer of formula (A) is 49.5 parts by weight, the monomer of formula (B) is 1 parts by weight, the monomer of formula (C) is 0.75 parts by weight, and the monomer of formula (D) is 0.75 parts by weight;
resin 4: in parts by weight, the monomer of formula (A) is 42.5 parts by weight, the monomer of formula (B) is 7.5 parts by weight, the monomer of formula (C) is 1.5 parts by weight, and the monomer of formula (D) is 1 parts by weight.

6. The resin according to claim 5, wherein
in the resin 1, the weight average molecular weight of the resin is 9800; the molecular weight distribution coefficient of the resin is 2;
or in the resin 2, the weight average molecular weight of the resin is 6400; the molecular weight distribution coefficient of the resin is 1.7;
or in the resin 3, the weight average molecular weight of the resin is 6300; the molecular weight distribution coefficient of the resin is 1.5;
or in the resin 4, the weight average molecular weight of the resin is 7200; the molecular weight distribution coefficient of the resin is 1.7.

7. A preparation method for the resin according to claim 1, wherein the preparation method comprises the following steps: carrying out a polymerization reaction involving the monomer of formula (A), the monomer of formula (B), the monomer of formula (C), and the monomer of formula (D) in an organic solvent to obtain the resin.

8. The preparation method according to claim 7, wherein
in parts by weight, the organic solvent is 50 to 300 parts by weight;
or the organic solvent is one or more of propylene glycol methyl ether acetate, propyleneglycol diacetate, methylenebisacrylamide, N-methylpyrrolidone, ethyl 3-ethoxypropionate and cyclohexanone and dichloromethane;
or the polymerization reaction is carried out under an inert gas;
or the polymerization reaction is initiated by a free radical initiator or by heating;
or the time of the polymerization reaction is 6 to 12 hours;
or the polymerization reaction further comprises post-treatment steps, the post-treatment steps are one or more of cooling, precipitation, and drying;
or the preparation method comprises the following steps: adding a solution of the monomer of formula (A), the monomer of formula (B), the monomer of formula (C), and the monomer of formula (D) and part of the organic solvent, to the rest of the organic solvent.

9. The preparation method according to claim 8, wherein in in parts by weight, the organic solvent is 100 parts by weight;
or the organic solvent is propylene glycol methyl ether acetate;
or the inert gas is nitrogen;
or when the polymerization reaction is initiated by a free radical initiator, the free radical initiator is one or more of 2,2′-azobis(isobutyronitrile), 2,2′-azobis(2,4-dimethylvaleronitrile), 2,2′-azobis(methyl 2-methylpropionate), benzoyl peroxide, and lauroyl peroxide; when the polymerization reaction is initiated by heating, the temperature of the polymerization reaction is 50 to 150° C.;
or the time of the polymerization reaction is 8 hours;
or the solvent used in the precipitation is an alcohol solvent; the drying is vacuum drying;
or the mass ratio of the part of the organic solvent to the rest of the organic solvent is 5:1 to 1:1; the adding mode is dropwise addition; the time of addition is 1 to 8 hours.

10. The preparation method according to claim 9, wherein when the polymerization reaction is initiated by heating, the temperature of the polymerization reaction is 60 to 90° C.;
or the solvent used in the precipitation is methanol;
or the drying is vacuum drying at 40° C. for 24 hours;
or the mass ratio of the part of the organic solvent to the rest of the organic solvent is 7:3;
or the time of addition is 5 hours.

11. The preparation method according to claim 10, wherein when the polymerization reaction is initiated by heating, the temperature of the polymerization reaction is 70° C.

12. A photoresist composition, wherein the photoresist composition comprises a resin, a photoacid generator, and a solvent;
or the photoresist composition comprises a resin, a photoacid generator, a solvent, and an additive;
the resin is defined as claim 1.

13. The photoresist composition according to claim 12, wherein the photoacid generator has a structure of formula (I): 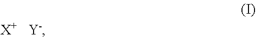
wherein X⁺ is selected from any one of the following structures: 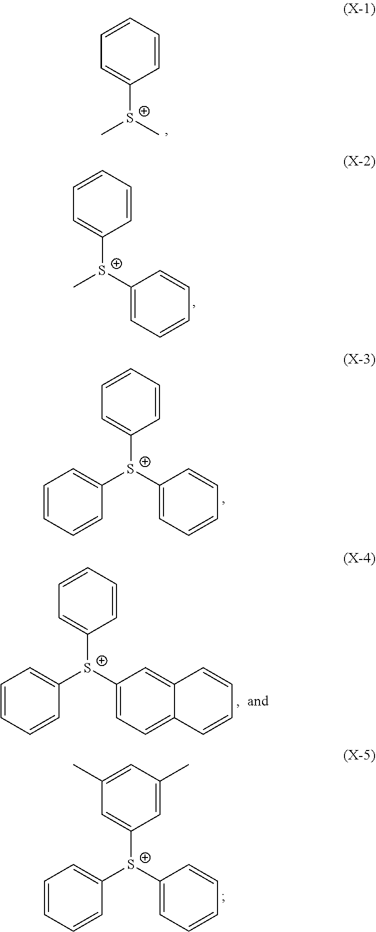
Y⁻ is selected from any one of the following structures: 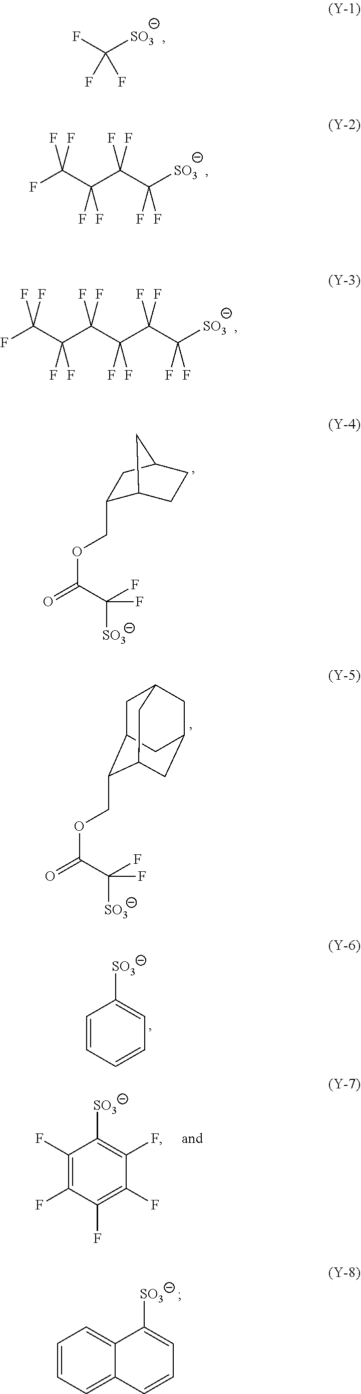
or the solvent is one or more of ketone solvent, ether solvent, ester solvent, and alcohol solvent;
or the additive is a quencher or a surfactant.

14. The photoresist composition according to claim 13, wherein the photoacid generator is selected from any one of the following structures: 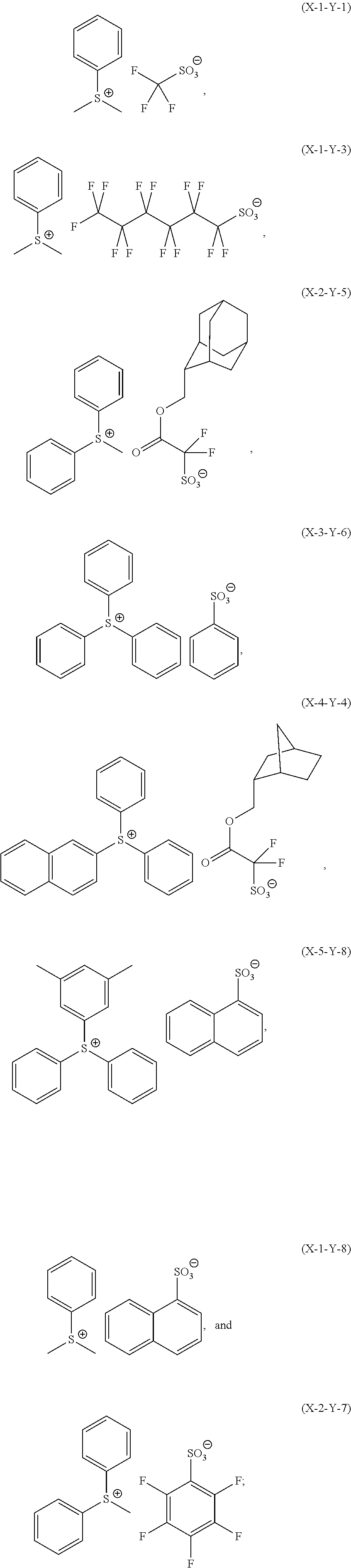
or the solvent is one or more of cyclohexanone, ethylene glycol monoethyl ether, and γ-butyrolactone;
or the quencher is 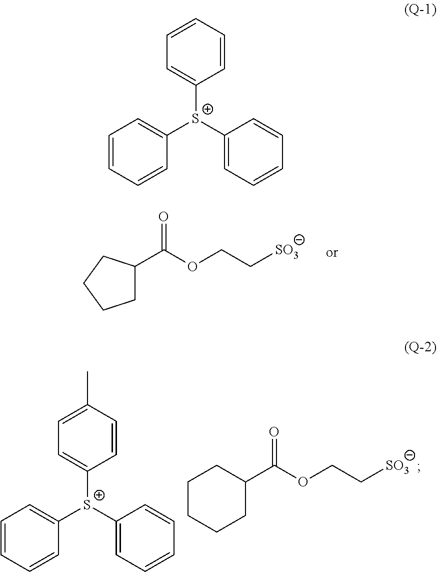
or the surfactant is one or more of FC-4430, S-381, E1004, KH-20, and KH-30;
or in parts by weight, the resin is 75 to 95 parts by weight;
or in parts by weight, the photoacid generator is 1 to 10 parts by weight;
or in parts by weight, the solvent is 1000 to 2000 parts by weight;
or in parts by weight, the quencher is 0.5 to 3 parts by weight;
or in parts by weight, the surfactant is 0.1 to 0.2 parts by weight.

15. The photoresist composition according to claim 14, wherein the surfactant is KH-20 or KH-30;
or in parts by weight, the resin is 85 parts by weight;
or in parts by weight, the photoacid generator is 7 parts by weight;
or in parts by weight, the solvent is 1500 parts by weight;
or in parts by weight, the quencher is 2 parts by weight;
or in parts by weight, the surfactant is 0.15 parts by weight.

16. The photoresist composition according to claim 12, wherein the photoresist composition can be selected from any one of the following combinations 1-4:
combination 1: in parts by weight, resin 1 is 85 parts by weight, the photoacid generator X-1-Y-1 is 7 parts by weight, the solvent cyclohexanone is 1500 parts by weight, the quencher Q-1 is 2 parts by weight, the surfactant KH-30 is 0.15 parts by weight;
combination 2: in parts by weight, resin 2 is 85 parts by weight, the photoacid generator X-1-Y-1 is 7 parts by weight, the solvent cyclohexanone is 1500 parts by weight, the quencher Q-1 is 2 parts by weight, the surfactant KH-30 is 0.15 parts by weight;
combination 3: in parts by weight, resin 3 is 85 parts by weight, the photoacid generator X-1-Y-1 is 7 parts by weight, the solvent cyclohexanone is 1500 parts by weight, the quencher Q-1 is 2 parts by weight, the surfactant KH-30 is 0.15 parts by weight;
combination 4: in parts by weight, resin 4 is 85 parts by weight, the photoacid generator X-1-Y-1 is 7 parts by weight, the solvent cyclohexanone is 1500 parts by weight, the quencher Q-1 is 2 parts by weight, the surfactant KH-30 is 0.15 parts by weight;
wherein, in the resin 1: in parts by weight, the monomer of formula (A) is 45 parts by weight, the monomer of formula (B) is 4 parts by weight, the monomer of formula (C) is 0.25 parts by weight, and the monomer of formula (D) is 0.75 parts by weight;
in the resin 2: in parts by weight, the monomer of formula (A) is 42.5 parts by weight, the monomer of formula (B) is 4 parts by weight, the monomer of formula (C) is 1.75 parts by weight, and the monomer of formula (D) is 1.75 parts by weight;
in the resin 3: in parts by weight, the monomer of formula (A) is 49.5 parts by weight, the monomer of formula (B) is 1 parts by weight, the monomer of formula (C) is 0.75 parts by weight, and the monomer of formula (D) is 0.75 parts by weight;
in the resin 4: in parts by weight, the monomer of formula (A) is 42.5 parts by weight, the monomer of formula (B) is 7.5 parts by weight, the monomer of formula (C) is 1.5 parts by weight, and the monomer of formula (D) is 1 parts by weight.

17. A method for forming a photolithographic pattern, wherein the method comprises the following steps:
S1: coating the substrate surface with the photoresist composition according to claim 12 and baking to form a photoresist layer;
S2: exposing the photoresist layer formed in S1;
S3: baking the exposed photoresist layer exposed in S2;
S4: developing the baked photoresist layer baked in S3.

18. The method according to claim 17, wherein in S1, the substrate is a substrate for the manufacture of integrated circuits, or a substrate for the manufacture of mask circuits;
or in S1, the method of coating is spin coating;
or in S1, the baking temperature is 120 to 250° C.;
or in S1, the baking time is 1 to 10 minutes;
or in S1, the thickness of the photoresist layer is 0.05 to 2 μm;
or in S2, the exposure is carried out using high-energy radiation exposure or electron beam exposure;
or in S3, the baking temperature is 60 to 150° C.;
or in S3, the baking time is 1 to 3 minutes;
or in S3, after the baking, the step further comprises a step of cooling;
or in S4, the method of development is one or more of immersion, spin-coating immersion, and spraying;
or in S4, a developer used for the development is an alkaline aqueous solution or an organic solvent;
or in S4, the development temperature is 10 to 30° C.;
or in S4, the development time is 0.1 to 3 minutes.

19. The method according to claim 17, wherein,
in S1, the substrate used in the manufacture of integrated circuits is one or more of Si, SiO₂, SiN, SiON, TiN, WSi, BPSG, SOG, and organic anti-reflective coatings;
or in S1, the substrate used in the manufacture of mask circuits is one or more of Cr, CrO, CrON, MoSi₂, and SiO₂;
or in S1, the baking temperature is 130° C.;
or in S1, the baking time is 1 minute;
or in S1, the thickness of the photoresist layer is 300 nm;
or in S2, when the exposure is carried out using high-energy radiation exposure, the high-energy radiation is KrF excimer laser, ArF excimer laser, or EUV, and the dose of exposure is 1 to 200 mJ/cm²;
or in S2, when the exposure is carried out using electron beam exposure, the dose of exposure is 0.1 to 100 μC/cm²;
or in S3, the baking temperature is 80 to 140° C.;
or in S3, the baking time is 1 minute;
or in S3, after the baking, the step further comprises a step of cooling to 10-30° C.;
or in S4, the alkaline aqueous solution is 0.1-5 wt % of tetramethylammonium hydroxide aqueous solution;
or in S4, the organic solvent can be one or more of 2-octanone, 2-nonanone, 2-heptanone, 3-heptanone, 4-heptanone, 2-hexanone, 3-hexanone, diisobutyl ketone, methyl cyclohexanone, acetophenone, methyl acetophenone, propyl acetate, butyl acetate, isobutyl acetate, pentyl acetate, isopentyl acetate, butenyl acetate, benzyl acetate, propyl formate, butyl formate, isobutyl formate, pentyl formate, isopentyl formate, methyl valerate, methyl crotonate, methyl ricinoleate, ethyl ricinoleate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, benzyl acetate, methyl phenylacetate, benzyl formate, ethyl phenylformate, methyl 3-phenylpropionate, benzyl propionate, ethyl phenylacetate, and ethyl 2-phenylacetate;
or in S4, the development temperature is 23° C.;
or in S4, the development time is 0.5 to 2 minutes.

20. The method according to claim 19, wherein,
in S2, when the exposure is carried out using high-energy radiation exposure, the high-energy radiation is KrF excimer laser, ArF excimer laser, or EUV, and the dose of exposure is 10 to 100 mJ/cm²;
or in S2, when the exposure is carried out using electron beam exposure, the dose of exposure is 0.5 to 50 μC/cm²;
or in S3, the baking temperature is 115° C.;
or in S3, after the baking, the step further comprises a step of cooling to 23° C.;
or in S4, the alkaline aqueous solution is 2-3 wt % of tetramethylammonium hydroxide aqueous solution;
or in S4, the development time is 1 minute.
